(19) United States
(12) Patent Application Publication
(10) Pub. No.: US 2022/0341052 A1
(43) Pub. Date: Oct. 27, 2022

(54) ELECTRONIC DEVICE HOUSINGS WITH ELECTROLESS PLATING LAYERS

(71) Applicant: Hewlett-Packard Development Company, L.P., Spring, TX (US)

(72) Inventors: Qingyong Guo, Shanghai (CN); Kuan-Ting Wu, Taipei City (TW); Ya Cheng Chuang, Shanghai (CN); Feng Gu, Shanghai (CN)

(73) Assignee: Hewlett-Packard Development Company, L.P., Spring, TX (US)

(21) Appl. No.: 17/637,238

(22) PCT Filed: Oct. 31, 2019
(86) PCT No.: PCT/CN2019/114821

§ 371 Date: Feb. 22, 2022

(51) Int. Cl. C25D 13/12; H05K 5/04; C25D 13/20; C23C 18/16; C23C 18/18; C23C 28/00

(52) U.S. Cl. CPC C25D 13/12; H05K 5/04; C25D 13/20; C23C 18/1637; C23C 18/1651; C23C 18/1803; C23C 28/44

(57) ABSTRACT

In one example, an electronic device housing may include a substrate, a micro-arc oxidation layer formed on a surface of the substrate, and an electroless plating layer formed on the micro-arc oxidation layer. Example electroless plating layer may be one of an electroless tin plating layer and an electroless silver plating layer. Further, the electronic device housing may include an electrophoretic deposition layer formed on the electroless plating layer.

### BACKGROUND

In recent years, metal housings with lightweight and high rigidity properties have become popular since the portable electronic products are developed to be lighter and smaller. In such requirements, metal housings may be manufactured using metal substrates such as magnesium alloy, aluminum alloy, or the like. Further, the technology of composite material that combines the metal housings with plastic members or carbon fiber members has become a focus in the industry. Composite materials may refer to materials made from two or more constituent materials with different physical properties. The resultant housings with the composite materials may have high strength and low density.

### BRIEF DESCRIPTION OF THE DRAWINGS

Examples are described in the following detailed description and in reference to the drawings, in which:

FIG. 1 illustrates a cross-sectional side view of an example electronic device housing, depicting an electroless plating layer and an electrophoretic deposition layer;

FIG. 2 illustrates a cross-sectional side view of an example electronic device housing, depicting a first electroless plating layer and a second electroless plating layer;

FIG. 3 illustrates an example flowchart for making a casing or housing for an electronic device;

FIG. 4 illustrates another example flowchart for making a casing or housing for an electronic device;

FIG. 5 illustrates yet another example flowchart for making a casing or housing for an electronic device; and

FIG. 6 illustrates yet another example flowchart for making a casing or housing for an electronic device.

### DETAILED DESCRIPTION

Housings for electronic devices such as mobile phones, laptop computers, music players, personal digital assistants, global positioning system devices, and the like can be made by plastic and/or metal. Metal housings may have a better mechanical strength, but are electrically conductive, which may weaken the communication signals. Plastic housings may be non-conductive, but may lack mechanical strength. Some housings may have composite materials such as a combination of plastic material and metal. For example, a housing may include a plastic layer and a metal layer assembled to achieve both good communication and mechanical strength. For instance, an outer layer of a housing portion may be formed by a metal layer, which may be supported by an inner plastic layer. The outer metal layer may provide a wear resistant, robust, and aesthetic appearance to the housing.

Example metal layer may be a magnesium or magnesium alloy layer. Because of the light weight and high mechanical strength, magnesium alloys may be suitably used in housings for electronic devices. However, the magnesium alloy layer may have poor color stability, hardness, and chemical resistance. Therefore, it may be difficult to fabricate metallic luster appearance with smooth tactile touch feeling at surfaces of the housings as the magnesium alloys can be oxidized on the surface.

In some examples, an oxide layer may be formed on the metal layer to resolve the issue of oxidization of the magnesium alloy. However, forming the oxide layer on the metal layer may result in significantly low gloss and matt surface texture on the housings. Further, forming an electrophoretic deposition layer (e.g., to impart certain desired properties, such as hardness or toughness, or a certain desired appearance to the housings) on the oxide layer may not meet industrial design needs because of significantly low whiteness and non-uniform touch feeling formed on the surface of the housings.

Examples described herein may provide an electronic device housing with electroless plating layers. The electronic device housing may include a substrate, a micro-arc oxidation layer formed on a surface of the substrate, and an electroless plating layer formed on the micro-arc oxidation layer. Example electroless plating layer may include an electroless nickel plating layer, electroless tin plating layer, an electroless silver plating layer, or any combination thereof. Further, the electronic device housing may include an electrophoretic deposition layer formed on the electroless plating layer.

Examples described herein may provide metallic luster appearance with uniform tactile touch feeling and significantly high whiteness surface finish on electronic device housings. Thus, examples described herein may enhance aesthetic appearance of the electronic device housings.

In the following description, for purposes of explanation, numerous specific details are set forth in order to provide a thorough understanding of the present techniques. It will be apparent, however, to one skilled in the art that the present apparatus, devices and systems may be practiced without these specific details. Reference in the specification to “an example” or similar language means that a particular feature, structure, or characteristic described is included in at least that one example, but not necessarily in other examples.

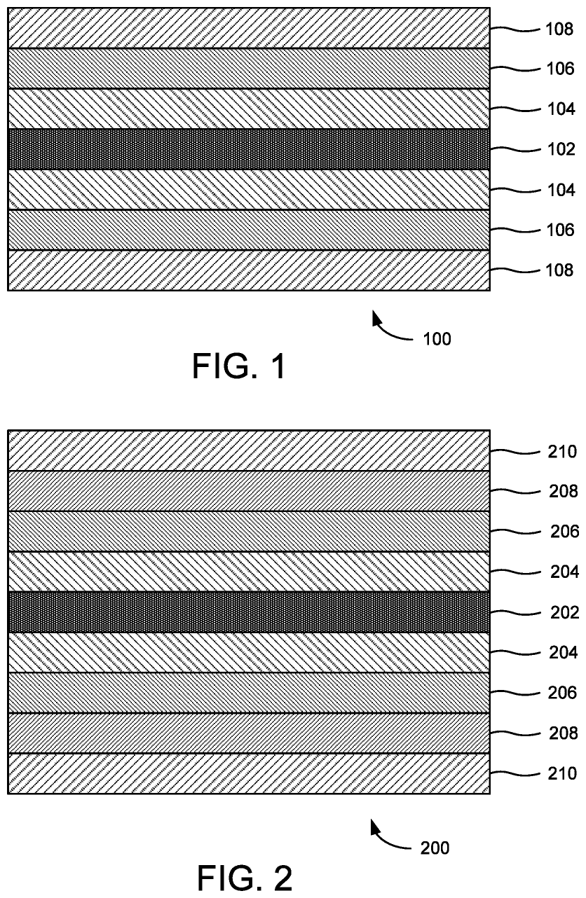

Turning now to the figures, FIG. 1 illustrates a cross-sectional side view of an example electronic device housing 100, depicting an electroless plating layer 106 and an electrophoretic deposition layer 108. Example electronic device housing 100 may include a smart phone housing, tablet or notebook personal computer housing, digital camera housing, or the like. Further, electronic device housing 100 may be implemented as a part of a top cover of a display housing, a bottom cover of a keyboard housing, or a combination thereof.

As shown in FIG. 1, example electronic device housing 100 may include a substrate 102. In one example, substrate 102 may include aluminium, magnesium, titanium, lithium, niobium, aluminium alloy, magnesium alloy, titanium alloy, lithium alloy, niobium alloy, or any combination thereof. In another example, substrate 102 may include a metal layer, a non-metal layer formed on a surface of the metal layer, or a combination thereof. Example non-metal layer may include plastic, carbon-fiber composite, or a combination thereof.

Further, electronic device housing 100 may include a micro-arc oxidation layer 104 formed on a surface of substrate 102. Example surface may face an exterior of electronic device housing 100, an interior of electronic device housing 100, or a combination thereof. Micro-arc oxidation layer 104 may be formed to provide chemically and mechanically protective oxide film on the surface of substrate 102. In one example, micro-arc oxidation layer 104 may have a thickness in a range of 3-15 μm.

Furthermore, electronic device housing 100 may include electroless plating layer 106 formed on micro-arc oxidation layer 104. In one example, electroless plating layer 106 may be one of an electroless tin plating layer and an electroless silver plating layer. Electroless plating layer 106 may be formed using an electroless plating process to provide uniformity and corrosion resistance for electronic device housing 100. Example electroless plating layer 106 may have a thickness in a range of 5-30 μm.

As shown in FIG. 1, electronic device housing 100 may include electrophoretic deposition layer 108 formed on electroless plating layer 106. Example electrophoretic deposition layer 108 may include polymer, such as polyacrylic polymer or epoxy polymer, in combination with inorganic and/or metallic particles. Electrophoretic deposition layer 108 may be used to impart a certain desired property, such as a hardness or toughness, or a certain desired appearance to electronic device housing 100. In one example electrophoretic deposition layer 108 may have a thickness in a range of 5-40 μm.

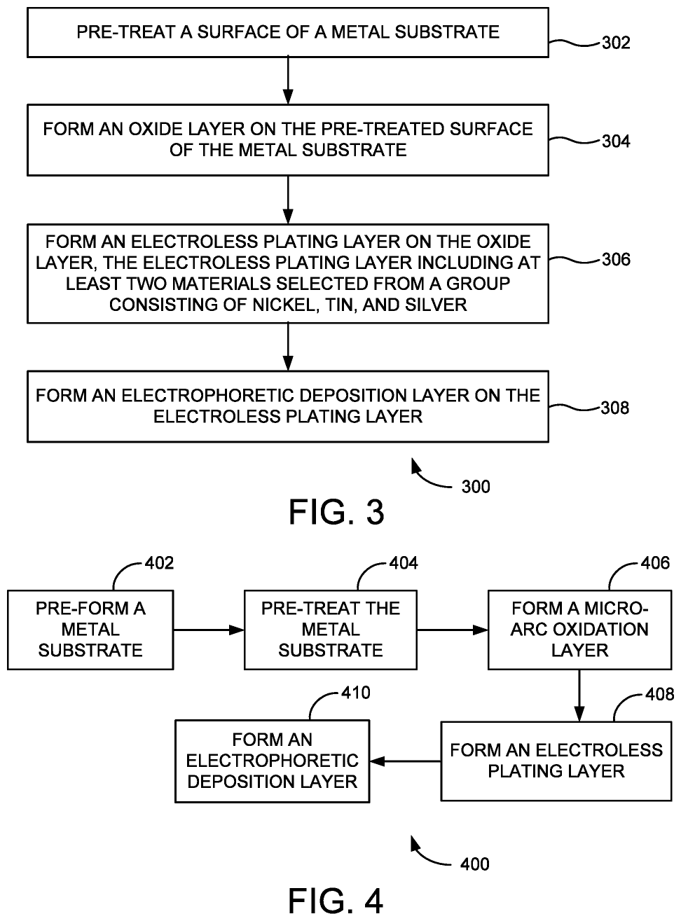

FIG. 2 illustrates a cross-sectional side view of an example electronic device housing 200, depicting a first electroless plating layer 206 and a second electroless plating layer 208. Example electronic device housing 200 may be a display housing, a keyboard housing, or a combination thereof. In one example, the keyboard housing may rotatably, detachably, or twistably connected to the display housing. As shown in FIG. 2, example electronic device housing 200 may include a substrate 202. Further, electronic device housing 200 may include a micro-arc oxidation layer 204 formed on a surface of substrate 202. In one example, micro-arc oxidation layer 204 may be formed on the surface of substrate 202 using a micro-arc oxidation process. Example micro-arc oxidation process is described in FIG. 3.

Further, electronic device housing 200 may include first electroless plating layer 206 formed on micro-arc oxidation layer 204. In one example, first electroless plating layer 206 may be an electroless nickel plating layer. Furthermore, electronic device housing 200 may include second electroless plating layer 208 formed on first electroless plating layer 206. Example second electroless plating layer 208 may be different from first electroless plating layer 206. In one example, second electroless plating layer 208 may be an electroless silver plating layer. In another example, second electroless plating layer 208 may be an electroless tin plating layer.

First electroless plating layer 206 and second electroless plating layer 208 may be formed using a first electroless plating process and a second electroless plating process, respectively. Thus, electronic device housing 200 may include multiple electroless plating layers (e.g., 206 and 208) formed on micro-arc oxidation layer 204. In other examples, first electroless plating layer 206 and second electroless plating layer 208 may be selected from a group consisting of electroless tin plating layer, electroless silver plating layer, and electroless nickel plating layer.

As shown in FIG. 2, electronic device housing 200 may include electrophoretic deposition layer 210 formed on second electroless plating layer 208. In one example, electrophoretic deposition layer 210 may be formed on second electroless plating layer 208 using an electrophoretic deposition. Example electrophoretic deposition is described in FIG. 3.

FIG. 3 illustrates an example flowchart 300 for making a casing or housing for an electronic device. Example casing may be a part of a display housing that houses a display, a keyboard housing that houses a keyboard, or a combination thereof. At 302, a surface of a metal substrate may be pre-treated. For example, the surface of the metal substrate may be pre-treated using an alkaline cleaning process, degreasing cleaning process, an acidic cleaning process, or any combination thereof. In other examples, prior to pre-treating the surface of the metal substrate, the metal substrate may be formed into a desired shape by at least one of computer numerical control machining, forging, and thixomolding the metal substrate.

At 304, an oxide layer may be formed on the pre-treated surface of the metal substrate. In one example, the oxide layer may be formed on the pre-treated surface of the metal substrate by applying one of a micro-arc oxidation process and a passivation treatment. The micro-arc oxidation process and the passivation treatment may be electrochemical surface treatment processes for generating oxide coatings on the metal substrate.

For example, the micro-arc oxidation process may refer to a process for generating oxide coatings on the metal substrate. During the micro-arc oxidation process, the metal substrate may be placed in an electrolytic solution including electrolytes selected from a group consisting of sodium silicate, sodium phosphate, potassium fluoride, potassium hydroxide, sodium hydroxide, fluorozirconate, sodium hexametaphosphate, sodium fluoride, aluminum oxide, silicon dioxide, ferric ammonium oxalate, phosphoric acid salt, and polyethylene oxide alkylphenolic ether. The electrolyte may be present in a concentration of 0.05 to 15% by weight based on the total weight of the electrolytic solution and a voltage in the range of 200-600 volts may be passed across the electrolytic solution with the metal substrate (e.g., magnesium alloy substrate) placed in the electrolytic solution to form a micro-arc oxidized layer (i.e., the oxide layer). In one example, the voltage may be applied for about 3 to 20 minutes and the micro-arc oxidation process can be carried out at a temperature between room temperature and 45° C. The thickness of the micro-arc oxide layer can be in the range of 3-15 μm. The micro-arc oxidation properties may include wearing resistance, corrosion resistance, high hardness, and electrical insulation.

Similarly, the passivation treatment may refer to a process of treating or coating the metal substrate to reduce the chemical reactivity of a surface of the metal substrate. For example, the passivation treatment may involve creation of an outer layer of shield material around the metal substrate to make the metal substrate “passive”, i.e., less affected or corroded by the environment.

In other examples, a non-metal layer may be formed on one side of the metal substrate prior to forming the oxide layer. At 306, an electroless plating layer may be formed on the oxide layer. Example electroless plating layer may include at least two materials/metals selected from a group consisting of nickel, tin, and silver. The electroless plating layer may be formed using an electroless plating process. For example, electroless plating process of metals such as silver, nickel, and/or tin may form a uniform coating of metallic layer on the oxide layer through chemical reduction of metal ions in an aqueous solution and subsequent deposition of metals without the use of electrical energy.

At 308, an electrophoretic deposition layer may be formed on the electroless plating layer. In one example, the electrophoretic deposition layer may be formed by applying an electrophoretic deposition on the electroless plating layer. The electrophoretic deposition may be a process in which the metal substrate with the electroless plating layer is placed in a fluid and a potential difference is applied to cause charged particles in the fluid to be deposited on the electroless plating layer.

FIG. 4 illustrates another example flowchart 400 for manufacturing a casing or housing of an electronic device. At 402, a metal substrate may be pre-formed. Example metal substrate may be a metal substrate, metal-plastic composite substrate, a metal-carbon fiber composite substrate, or the like. In one example, pre-forming the metal substrate may include forging, thixomolding, die casting, and/or computer numerical control (CNC) machining the metal substrate into a desired shape. At 404, the metal substrate may be pre-treated. For example, the forged, thixomolded, die casted, and/or CNC machined metal substrate may be pre-treated using a pre-cleaning process such as an alkaline cleaning process, degreasing cleaning process, an acidic cleaning process, or any combination thereof.

At 406, a micro-arc oxidation layer may be formed on a surface of the metal substrate. At 408, an electroless plating layer may be formed on the micro-arc oxidation layer. In one example, the electroless plating layer may include at least two materials selected from a group consisting of nickel, tin, and silver. At 410, an electrophoretic deposition layer may be formed on the electroless plating layer. In one example, the electrophoretic deposition may provide uniform tactile touch feeling finishing for the casing of the electronic device.

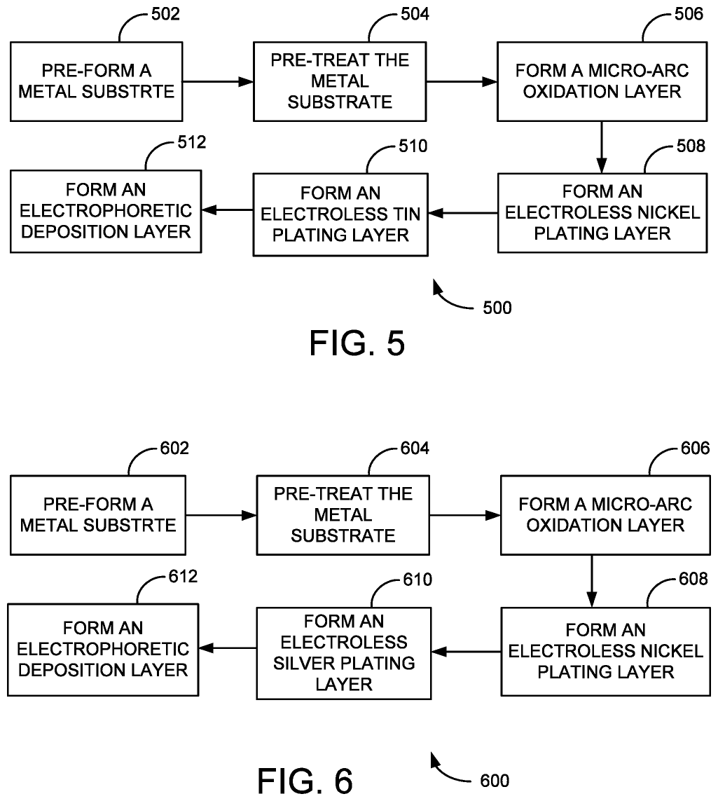

FIG. 5 illustrates yet another example flowchart 500 for manufacturing a casing or housing of an electronic device. At 502, a metal substrate may be pre-formed. At 504, the metal substrate may be pre-treated. At 506, a micro-arc oxidation layer may be formed on a surface of the metal substrate. At 508, an electroless nickel plating layer may be formed on the micro-arc oxidation layer. At 510, an electroless tin plating layer may be formed on the electroless nickel plating layer. At 512, an electrophoretic deposition layer may be formed on the electroless tin plating layer.

FIG. 6 illustrates yet another example flowchart 600 for manufacturing a casing or housing of an electronic device. At 602, a metal substrate may be pre-formed. At 604, the metal substrate may be pre-treated. At 606, a micro-arc oxidation layer may be formed on a surface of the metal substrate. At 608, an electroless nickel plating layer may be formed on the micro-arc oxidation layer. At 610, an electroless silver plating layer may be formed on the electroless nickel plating layer. At 612, an electrophoretic deposition layer may be formed on the electroless silver plating layer.

It should be understood that example flowcharts 300, 400, 500, and 600 represent generalized illustrations, and that other processes may be added, or existing processes may be removed, modified, or rearranged without departing from the scope and spirit of the present application. Further, example flowcharts 300, 400, 500, and 600 may not intended to limit the implementation of the present application, but rather example flowcharts 300, 400, 500, and 600 illustrate functional information to design/fabricate circuits, generate machine-readable instructions, or use a combination of hardware and machine-readable instructions to perform the illustrated processes.

It may be noted that the above-described examples of the present solution are for the purpose of illustration only. Although the solution has been described in conjunction with a specific implementation thereof, numerous modifications may be possible without materially departing from the teachings and advantages of the subject matter described herein. Other substitutions, modifications and changes may be made without departing from the spirit of the present solution. All of the features disclosed in this specification (including any accompanying claims, abstract, and drawings), and/or all of the steps of any method or process so disclosed, may be combined in any combination, except combinations where at least some of such features and/or steps are mutually exclusive.

The terms “include,” “have,” and variations thereof, as used herein, have the same meaning as the term “comprise” or appropriate variation thereof. Furthermore, the term “based on”, as used herein, means “based at least in part on.” Thus, a feature that is described as based on some stimulus can be based on the stimulus or a combination of stimuli including the stimulus.

The present description has been shown and described with reference to the foregoing examples. It is understood, however, that other forms, details, and examples can be made without departing from the spirit and scope of the present subject matter that is defined in the following claims.

What is claimed is:

1. An electronic device housing comprising:
a substrate;
a micro-arc oxidation layer formed on a surface of the substrate;
an electroless plating layer formed on the micro-arc oxidation layer, wherein the electroless plating layer is one of an electroless tin plating layer and an electroless silver plating layer; and
an electrophoretic deposition layer formed on the electroless plating layer.

2. The electronic device housing of claim 1, wherein the substrate comprises aluminium, magnesium, titanium, lithium, niobium, aluminium alloy, magnesium alloy, titanium alloy, lithium alloy, niobium alloy, or any combination thereof.

3. The electronic device housing of claim 1, wherein the substrate comprises:
a metal layer; and
a non-metal layer formed on a surface of the metal layer, the surface of the metal layer facing an interior of the electronic device housing.

4. The electronic device housing of claim 1, wherein the micro-arc oxidation layer has a thickness in a range of 3-15 μm.

5. The electronic device housing of claim 1, wherein the electroless plating layer has a thickness in a range of 5-30 μm.

6. The electronic device housing of claim 1, wherein the electrophoretic deposition layer has a thickness in a range of 5-40 μm.

7. An electronic device housing comprising:
a substrate;
a micro-arc oxidation layer formed on a surface of the substrate;
a first electroless plating layer formed on the micro-arc oxidation layer;
a second electroless plating layer formed on the first electroless plating layer, wherein the second electroless plating layer is different from the first electroless plating layer; and
an electrophoretic deposition layer formed on the second electroless plating layer.

8. The electronic device housing of claim 7, wherein the first electroless plating layer is an electroless nickel plating layer.

9. The electronic device housing of claim 7, wherein the second electroless plating layer is an electroless silver plating layer.

10. The electronic device housing of claim 7, wherein the second electroless plating layer is an electroless tin plating layer.

11. A method of making a casing for an electronic device, the method comprising:
pre-treating a surface of a metal substrate;
forming an oxide layer on the pre-treated surface of the metal substrate;
forming an electroless plating layer on the oxide layer, wherein the electroless plating layer comprises at least two materials selected from a group consisting of nickel, tin, and silver; and
forming an electrophoretic deposition layer on the electroless plating layer.

12. The method of claim 11, wherein the surface of the metal substrate is pre-treated using an alkaline cleaning process, degreasing cleaning process, an acidic cleaning process, or any combination thereof.

13. The method of claim 11, wherein the oxide layer is formed on the pre-treated surface of the metal substrate by applying one of a micro-arc oxidation process and a passivation treatment.

14. The method of claim 11, comprising:
forming the metal substrate into a desired shape by at least one of computer numerical control machining, forging, and thixomolding the metal substrate prior to pre-treating.

15. The method of claim 11, comprising:
forming a non-metal layer on one side of the metal substrate prior to forming the oxide layer.
